(19) United States
(12) Patent Application Publication
(10) Pub. No.: US 2015/0110969 A1
(43) Pub. Date: Apr. 23, 2015

(54) Low Stress Silicon Cladding for Optical Surface Finishing

(71) Applicant: David A. Sheikh, Encinitas, CA (US)

(72) Inventor: David A. Sheikh, Encinitas, CA (US)

(21) Appl. No.: 14/504,366

(22) Filed: Oct. 1, 2014

Related U.S. Application Data
(60) Provisional application No. 61/960,947, filed on Oct. 1, 2013.

(51) Int. Cl. C23C 14/58; G02B 5/08; C23C 14/24

(52) U.S. Cl. CPC C23C 14/5833; C23C 14/24; G02B 5/08
USPC 427/535

(57) ABSTRACT

A process for a low temperature, ion-assisted, evaporation technique (IAD), whereby the coating stress of a silicon film may be manipulated from compressive to tensile, in order to produce a near-zero net stress for the complete layer. A Si cladding with little intrinsic stress is essential to allow thick coatings to be manufactured without cracking. A low stress coating also minimizes substrate bending that would otherwise distort the figure of very lightweight mirrors. The proposed process takes less time so the surfaces may be polished to levels suitable for ultraviolet optical and infrared astronomy and is directly scalable to SiC mirrors several meters in diameter,

### CROSS REFERENCE TO RELATED APPLICATIONS

This application claims priority in provisional application No. 61/960,947 filed on Oct. 1, 2013 entitled “Low-Stress Silicon Cladding for Surface Finishing Large Mirrors

### FIELD OF THE INVENTION

The present invention relates to silicon carbide minors and in particular to such minors having a silicon surface coating.

### BACKGROUND OF THE INVENTION

Normal incidence 4-meter class UVOIR telescopes have been cited as a high priority by multiple government review panels including; the National Research Council's (NRC) study of NASA's Space Technology Roadmap and Priorities, The Office of the Chief Technologist, The Cosmic Origins Program and NWNH Decadal,

Over the past decade, significant US government funding has been allocated to lightweight silicon carbide mirror technology. Silicon carbide minors offer an exceptional stiffness to weight ratio and may offer significant advantages over light-weighted glass minors. Silicon cladding is potentially a key (and possibly an enabling) component of several types of silicon carbide mirror systems.

Current SiC minors are generally limited to less than 1-m in size because the surfacing technology currently available is based on a high temperature CVD Si cladding process. Although CVD cladding processes have been available for several years and are quite dependable, the high temperature requirements makes scaling the process to large mirrors several meters in diameter difficult and very expensive, or simply impractical. In addition, the CVD cladding technology typically yields a cladding with high intrinsic stress, which can bend very light-weighted minor substrates. The present invention's nearly room temperature IAD process yields low-coating stress and may be easily scaled to almost any size substrate, limited only by the size of the vacuum chamber.

Large silicon carbide (SiC) mirrors (2 to 5 meters in diameter) are being considered for future space-based UVOIR astronomy missions. These lightweight mirrors will likely require a highly-polishable layer of silicon (10 to 50 microns) applied on top of the SiC. A relatively thick layer of Si is desirable for the purpose of reducing figuring time and for achieving a super-polished surface, suitable for UV astronomy. Normal incidence 4-meter class ultraviolet, optical and infrared (UVOIR) telescopes have been cited as a high priority by multiple government review panels including; the National Research Council's (NRC) study of NASA's Space Technology Roadmap and Priorities, The Office of the Chief Technologist, The Cosmic Origins Program and NWNH Decadal.

### SUMMARY OF THE INVENTION

The present invention provides a better process for applying a low-stress silicon coating to silicon carbide mirrors. The process utilizes an ion-assisted, thermal evaporation process to apply silicon to the silicon carbide surface of the mirror blank. Silicon films made without ion bombardment have high intrinsic tensile stress. The high stress limits the coating thickness of silicon deposits to only about 1 micron. However by applying layers of silicon with the stress in each layer alternating from tensile to compressive, a near-zero net coating stress can be maintained and very thick silicon deposits (100 microns or more) may be created. Applicant has discovered that highly compressive silicon films may be created by bombarding the silicon film with 100-200 eV argon ions. Therefore Applicant can produce alternating compressive and tensile layers by making layers with and without ion bombardment with the result of near zero net coating stress. Lower anode voltages require higher argon gas flow for a given anode current. This is because the ion gun is less efficient at producing ions at lower anode voltages. The amount of argon trapped in the growing silicon film affects both the stress in the film and the electrical properties of the film.

The ion-assisted evaporation process is directly scalable to SiC mirrors several meters in diameter. The process is a low temperature, ion-assisted, vapor deposition (IAD) process yielding much better results than chemical vapor deposition processes that require much higher temperatures. A cladding with little intrinsic stress is essential to minimize bending that would otherwise distort the figure of very lightweight mirrors. A relatively thick layer of Si is desirable for the purpose of reducing figuring time and for achieving a super-polished surface, suitable for ultraviolet astronomy.

The benefits of the present invention include:
Scaleable to mirrors 5-meters in diameter
Relatively low temperature process (less than 80 C)
Low stress coating suitable for lightweight mirror structures
Allows SiC mirror substrate to be figured faster and more cost effectively
Allows SiC mirror substrate to be polished to mirror quality (goal less than 5 angstroms RMS for UV astronomy)

### DETAILED DESCRIPTION OF THE DRAWINGS

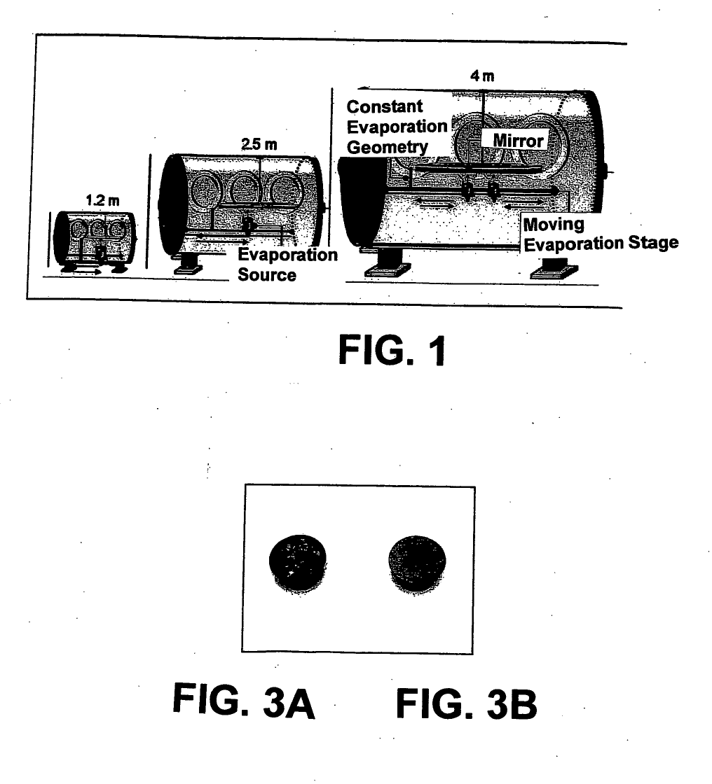

FIG. 1 shows three chamber sizes needed to coat mirrors ranging is mirror sizes 1.2 m, 2.5 m and 5 m.

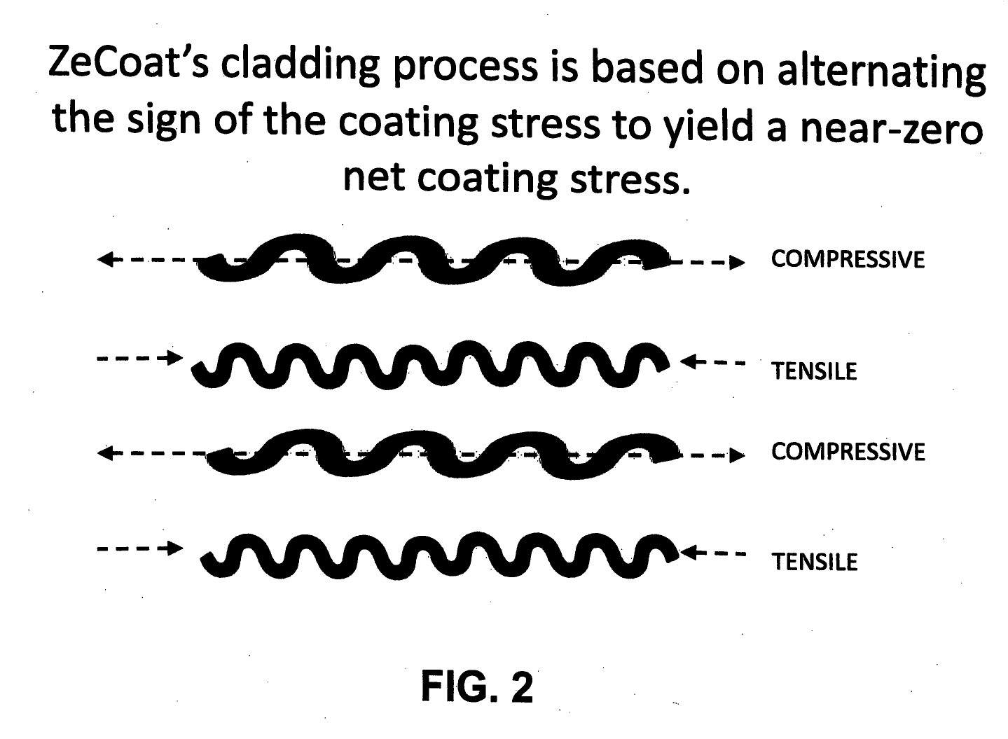

FIG. 2 shows alternating stresses between compressive and tensile.

FIGS. 3A and 3B respectively show a carbon liner filed with silicon pellets and pre-melted silicon for use in Applicant's coating process.

### DETAILED DESCRIPTION OF PREFERRED EMBODIMENTS

Preferred embodiments of the present invention are described below by reference to the figures.

Applicant has constructed a state-of-the-art 1.2 meter coating chamber shown in FIG. 1. This design can be utilized for larger chamber at 2.5 meters and 5 meters as also shown in FIG. 1. These chambers can be utilized for the development of silicon cladding technology, as well as, other coating technologies, such as reflective coatings, for large silicon carbide minors needed for telescopes for space-based astronomy. Applicant's new coating chamber features improvements to the motion-controlled deposition technology developed over the past decade.

The new chamber is equipped with a ball-screw driven, moving evaporation stage, a 10-pocket (40-cc) electron gun, and (2) ion sources. The electron gun, ion sources and power supplies utilized in Applicant's chamber are among the largest sizes available in the market. By developing processes based on large, powerful evaporation equipment and a fixed geometry between the evaporation source and the substrate, a coating process developed in this 1.2-m chamber can be directly transferred to a larger chamber without significant further development. In the case of a 5-meter minor, two or more evaporation sources could be driven back and forth along multiple radii to reduce processing time.

Mirrors coated in the 1.2 meter chamber can meet the following objectives:

| Si Coating Thickness | 50 | microns |
|---|---|---|
| Surface Roughness After | <5 | A RMS |
| Polishing | | |
| Scratch-dig | 60-40 MIL-PRF-13830 | |
| Coating Stress | <85 | MPa |

| | |
|---|---|
| Adhesion | ASTM Tape Test |
| Humidity | 50 C., 95% RH, 24 hr |
| Thermal Cycle | −80 C. + 150 C., 10-cycles |

These embodiments provide a better process for applying a low-stress silicon coating to silicon carbide minors. In general the processes utilize an ion assisted electron beam evaporation to apply silicon to the silicon carbide surface of the mirror blank. Stress resulting from mismatch between silicon and silicon carbide is minimized by applying alternating layers of silicon. Applicant has discovered that bombarding a growing silicon film with a sufficiently high flux of 100-200 eV argon ions, has an effect of changing the natural intrinsic stress in the coating from tensile to compressive. Therefore, Applicant can produce alternating compressive and tensile layers simply by turning on and off the ion flow, with the result of near zero net coating stress. Lower anode voltages require higher argon gas flow for a given anode current. This is because the ion gun is less efficient at producing ions at lower anode voltages. The amount of trapped argon gas in the growing film affects both the stress and the electrical properties of the silicon film.

The ion-assisted evaporation process is directly scalable to SiC mirrors several meters in diameter. The process is a low temperature, ion-assisted, vapor deposition (IAD) process yielding much better results than chemical vapor deposition processes that require much higher temperatures. A cladding with little intrinsic stress is essential to minimize bending that would otherwise distort the figure of very lightweight mirrors. A relatively thick layer of Si is desirable for the purpose of reducing figuring time and for achieving a super-polished surface, suitable for ultraviolet astronomy.

Applicant has discovered that relatively high compressive stress (of about 126-MPa) may be obtained by bombarding the depositing silicon film with 100-200 eV argon ions. The stress becomes tensile when the film is deposited in the absence of argon ions

In preferred embodiments Applicant can keep evaporation rates constant at 20-angstroms per second at all radial coating positions while maintaining an anode current on the ion gun of 7 amps.

### Evaporation Process

In preparation for applying the silicon coating, it is important to properly prepare the starting silicon material so as to avoid so-called “silicon spitting events:

So-called “silicon spitting events” may be described as micro-explosions of silicon that may occur during the evaporation process. When these micro-explosions occur, tiny “blobs” of molten silicon are thrown from the evaporation crucible and some of them may reach the substrate surface. The molten silicon melts in to the coated surface and creates defects ranging in size from a few microns in diameter to a few millimeters in diameter. These defects often may not be polished out, and can ruin a coating. A time consuming processes such as applying a 50-micron cladding to a large mirror, requires that these explosion events must be completely eliminated. We believe that these explosions are caused by several reasons including;

a. Too much electron beam power being dumped into a deposition crucible too quickly (excessively high deposition rate)
b. Too little silicon material in a crucible (causing too much power in the crucible for the amount of material remaining)
c. Cracks in the crucible liner (these cracks form after the liners are used several times). The cracks often form if e-gun power is cut rapidly, which causes rapid shrinking of the silicon as it cools, “pulling” on the walls of the liner. Hence, slow cooling of the molten silicon in the crucible minimizes this cracking problem. Since the crucible liners are relatively expensive ($150 each), it is not human nature to throw them away, often when they should be. Nevertheless, as the molten silicon eventually chemically reacts with the liner, the liners do eventually form cracks within a few uses and therefore must be discarded before the cracks are formed.

In preferred embodiments the silicon target is pre-conditioned using the following process:
1. Fill liner with silicon pellets and melt slowly with an electron beam at low power.
2. Once melted, allow the silicon to cool slowly with the electron beam remaining on at very low power, over a cool down period of about 15-minutes. Cooling too quickly causes the liner to crack.
3. Turn the electron beam off, allow the silicon too cool for 30 minutes and remove from the coating chamber.
4. Inspect liner for cracks and throw away damaged liners.
5. Top off the melt with fresh silicon pellets and place back in the vacuum chamber. The liner is approximately ⅔ full after the first melt.
6. Repeat steps 1 thru 4.
7. Remove the silicon melt from the chamber and if done correctly, the liner should have no cracks and the silicon should look like FIG. 3 below:

Since silicon is much softer than silicon carbide, silicon can be removed from the silicon carbide and polished without damaging the substrate. Portions can be grit blasted to provide the desired surface shape then polished. The choice of grit-blasting medium, particle size and blasting pressure must be carefully selected and optimized.

A question is: what is the relationship between initial substrate micro-roughness and the micro-roughness of the thick silicon cladding deposit, following the deposition of many microns of silicon? What initial SiC surface roughness is required for a given cladding thickness to still achieve a super-polish? The explanation is: As silicon cladding is applied to relatively rough silicon carbide substrate, the roughness increases, therefore, there is a limit to the amount of silicon that may be added to a rough substrate if it is to be polished to a mirror finish. For example, if the initial substrate has a matt finish and 50-microns of silicon are added, the substrate may become so rough that it can no longer be polished to a super-polished finish. So a trade-off may exist between applying enough silicon to allow economical figuring, while maintaining a final surface that is suitable for polishing. However, this concept may not be as limiting as it first sounds. For example, one could simply hand-polish (or otherwise polish) a poorly figured SiC substrate to a level of smoothness, which allows a relatively thick silicon cladding to be applied without compromising final polish.

Another question is: What is the maximum deposition rate that can be achieved while maintaining low coating stress and without Si spitting? The answer is: a compressively stressed coating is achieved by bombarding the surface with high energy ionized argon gas. On the other hand, silicon that is evaporated without this high energy bombardment has high tensile stress. By simply turning on and off the high-energy ionized argon periodically, the net coating stress in the cladding can be maintained to near-zero stress. Therefore, the limiting factor is the arrival ratio between the ionized argon gas and the deposition rate. The more ions one has, the faster a compressively stressed layer can be created, hence, the faster a stress-balanced laminate may be created.

### Variations

The foregoing description of preferred embodiments of the invention is presented for purposes of illustration and description and is not intended to be exhaustive or to limit the invention to the precise form disclosed. Modifications and changes may become apparent to those skilled in the art, and it is intended that the invention be limited only by the scope of the appended claims.

Applicant's technique balancing stress in a laminate for the purpose of minimizing bending in a lightweight mirror; by adjusting processing parameters, both compressively and tensile-stressed coating layers may be achieved. Another aspect of the present invention includes a method of preconditioning Si starting materials to eliminate the spitting problem. The conditioning method requires carefully melting silicon into insulating liners, which allows for high evaporation rates with no spitting. Another aspect of the present invention includes a method for using a custom designed thermal resistive heating source for the material deposition process in place of electron beam evaporation. A thermal resistive evaporation process may eliminate defects in the coating generated by e-beam deposition at high rates, which can cause localized boiling and defects in the deposited film. The use of resistive evaporation also eliminates high-voltage arcing, which also often accompanies electron beam evaporation and can interrupt the coating process resulting in higher coating costs. A low-voltage resistive evaporation source is used in place of the electron gun evaporation system may eliminate these problems. Another aspect of the present invention includes a process for controlling the background gas composition to control coating stress. Another aspect of the present invention includes a method for using a rotating substrate with a radially moving deposition source to apply a uniform coating layer, with uniform coating stress to a large substrate. By using this method of a motion-controlled deposition system, it is possible to apply a thin, silicon film across a large mirror by ‘scanning’ the evaporation source quickly down the radius of the minor, while the mirror is rotating.

What is claimed is:

1. A process for applying silicon to the silicon carbide surface of a mirror blank comprising:
A) utilizing electron beam source to evaporate a silicon target in order to apply silicon layers to the silicon carbide surface,
B) utilizing a thermal resistive evaporation source in place of the electron beam evaporation source to eliminate high voltage arcing and localized boiling, which may result in coating defects in the resulting silicon layers
C) utilizing a modulated argon ion bombardment technique to produce alternating stress in the silicon layers between compressive and tensile so as to produce near zero net coating stress in the silicon layers.

2. The process as in claim 1 wherein the compressive stress is produced with the ionized argon gas bombardment and the tensile stress is produced without the argon gas bombardment.

3. The process as in claim 1 wherein the compressive stress is produced with the high-energy ionized argon gas bombardment and the tensile stress is produced low-energy the argon gas bombardment.

4. The process as in claim 1 wherein the high-energy argon gas comprised argon ions having energies of about 100 to 200 eV.

5. The process as in claim 1 wherein electron gun is utilized to precondition silicon raw materials.

6. The process as in claim 1 wherein a thermal resistive heating source is utilized to eliminate electrical arcing and defects in the coating generated by e-beam deposition at high rates.

7. The process as in claim 1 wherein background gas composition is controlled to assist in controlling the coating stress.

8. The process as in claim 1 wherein lower anode voltages require higher argon gas flow for a given anode current.

9. The process as in claim 1 wherein a rotating substrate with a radially moving deposition source is used to apply a uniform coating layer, with uniform coating stress to a large substrate.

10. The process as in claim 1 wherein the low stress coating is utilize to minimize substrate bending that would otherwise distort the figure of very lightweight mirrors.
